(19) United States
(12) Patent Application Publication
(10) Pub. No.: US 2021/0400815 A1
(43) Pub. Date: Dec. 23, 2021

(54) SOLID STATE SWITCHING DEVICE INCLUDING HEAT SINKS AND CONTROL ELECTRONICS CONSTRUCTION

(71) Applicant: ABB Schweiz AG, Baden (CH)

(72) Inventors: Giovanni Salvatore, Zollikerberg (CH); Slavo Kicin, Zurich (CH)

(21) Appl. No.: 16/906,804

(22) Filed: Jun. 19, 2020

(51) Int. Cl. H05K 1/18; H05K 1/02; H05K 3/30; H05K 7/20; H02H 1/00; H02H 3/08

(52) U.S. Cl. CPC H05K 1/181; H05K 1/0203; H05K 3/303; H05K 7/209; H05K 2201/10189; H02H 3/08; H05K 2201/066; H05K 2201/10621; H05K 2201/10166; H02H 1/0007

(57) ABSTRACT

A solid state switching device, such as a solid state circuit breaker, includes at least one heat sink, a control electronics printed circuit board (PCB), and power electronics. The power electronics are useful to regulate the flow of current from one terminal of the solid state switching device to another terminal. The power electronics can include one or more solid state devices such as FETs, Thyristors, Thyristors+SiC JFET in parallel, IGBTs, and IGCTs. The control PCB can include a variety of circuit elements useful to perform the function of a gate driver useful to activate the solid state device of the power electronics. The control electronics can be positioned laterally to the power electronics and spanning from a heat sink positioned on one side of the power electronics to a heat sink positioned on an opposing side of the power electronics.

### TECHNICAL FIELD

The present disclosure generally relates to solid state switching devices, and more particularly, but not exclusively, to solid state circuit breakers having one or more heat sinks.

### BACKGROUND

The present disclosure relates generally to power switches such as solid state circuit breakers. Power systems need protection from fault currents that can damage power electronics converters, energy storage systems, capacitor banks, and other devices. Solid state circuit breakers can provide ultra-fast fault protection, load connection, and disconnection for a large variety of power critical applications. Existing solid state circuit breakers suffer from a number of shortcomings and disadvantages. There remain unmet needs including reducing device cost and reducing power losses during non-fault condition operations. For example, conventional solid state circuit breakers are costlier and incur higher conduction losses than traditional electromechanical circuit breakers. In view of these and other shortcomings in the art, there is a significant need for the unique apparatuses, methods, systems and techniques disclosed herein. Some existing systems have various shortcomings relative to certain applications. Accordingly, there remains a need for further contributions in this area of technology.

### SUMMARY

One embodiment of the present disclosure is a unique solid state circuit breaker. Other embodiments include apparatuses, systems, devices, hardware, methods, and combinations for positioning control electronics with respect to a heat sink of the solid state circuit breaker. Further embodiments, forms, features, aspects, benefits, and advantages of the present application shall become apparent from the description and figures provided herewith.

### BRIEF DESCRIPTION OF THE FIGURES

FIG. 1 depicts one embodiment of a solid state switching device.

FIG. 2 depicts one embodiment of a heat sink.

FIGS. 3A and 3B depict embodiments of solid state circuit breakers.

FIG. 4 depicts an embodiment of a heat sink and electronics package.

FIG. 5 depicts another embodiment of a heat sink and electronics package.

### DETAILED DESCRIPTION OF THE ILLUSTRATIVE EMBODIMENTS

For the purposes of promoting an understanding of the principles of the invention, reference will now be made to the embodiments illustrated in the drawings and specific language will be used to describe the same. It will nevertheless be understood that no limitation of the scope of the invention is thereby intended. Any alterations and further modifications in the described embodiments, and any further applications of the principles of the invention as described herein are contemplated as would normally occur to one skilled in the art to which the invention relates.

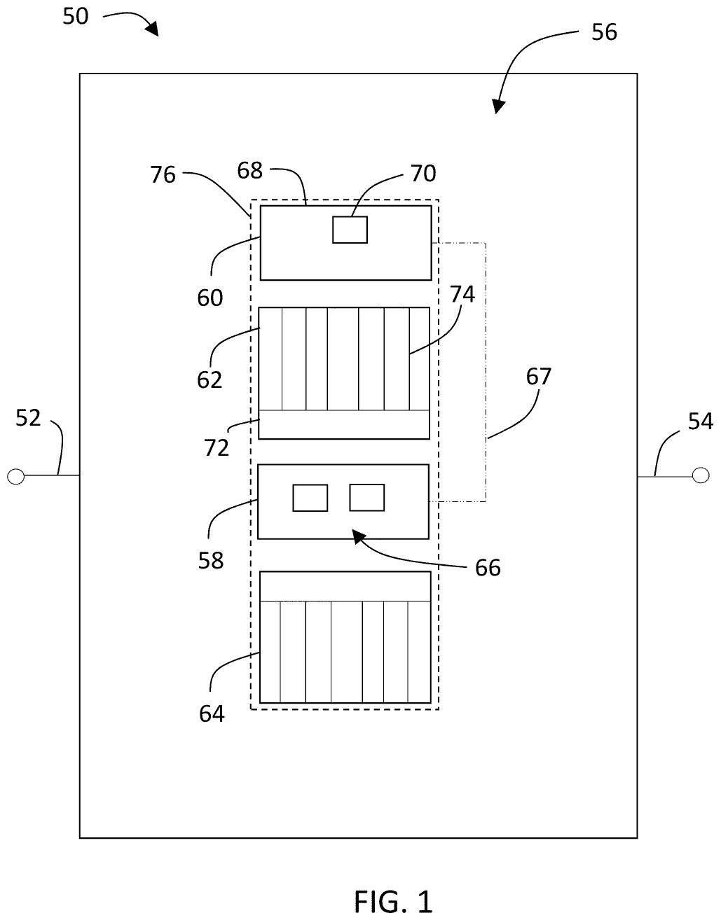

With reference to FIG. 1, a power switch 50 is illustrated which is useful to regulate (e.g. interrupt) current flow between terminals 52 and 54. In some forms the power switch 50 can take the form of a solid state circuit breaker (SSCB). For convenience of description below, reference will be made to solid state circuit breaker (SSCB) 50, but it will be understood that no limitation is hereby intended that the description below suitable for other types of power switches will nevertheless only be limited to SSBC's. For example, in certain embodiments, SSCB 50 may instead be another type of power switch including a solid state contactor, a status transfer switch, a utility disconnect switch, tie interconnect switch, bypass switch, another type of power switch structured to protect against faults, or another type of power switch structured to couple a power source to a load, to name but a few examples. It will also be appreciated that SSCB 50 may be implemented in a variety of applications, including low voltage DC power distribution systems, medium voltage DC power distribution systems, AC distribution systems, data centers, and shipboard power systems, to name but a few examples. In certain embodiments, low voltage may include any voltage less than 1500 V and medium voltage may include a range of voltages between 1500V and 73 kV.

The SSCB 50 includes the terminals 52 and 54, along with a heat sink and electronics package 56 which includes power electronics 58, control electronics printed circuit board (PCB) 60, as well as heat sinks 62 and 64 useful to remove heat from the power electronics 58. Although two heat sinks 62 and 64 are illustrated, in some forms the SSCB 50 may only include one heat sink. Additionally, in some forms either or both of the heat sinks 62 and 64 that are positioned on opposite sides of the power electronics 58 can include multiple heat sinks that together form a coordinated heat sink for that particular side of the power electronics 58. In those embodiments the heat sinks that together form a coordinated heat sink for a particular side of the power electronics 58 can, but need not, be identical. The components depicted in FIG. 1 can be ordered in the vertical manner illustrated, but other embodiments may include other ordering and/or location of components. For example, although the control electronics PCB 60 is shown ordered at the top of the stack of components, in some forms the control PCB 60 may be located to the lateral side of at least the power electronics 58.

The power electronics 58 includes a semiconductor switch configuration 66 which can include one or more semiconductor switching elements (two are shown in the schematic for illustrative purposes). The semiconductor switching elements can take a variety of forms including FETs, thyristors, thyristors+SiC JFET in parallel, IGBTs, IGCTs, or any other combinations of these forms, to set forth just a few non-limiting examples. The switching elements 66 are useful to regulate current between the terminals 52 and 54, such as but not limited to interrupting the current flow therebetween. In some non-limiting embodiments the SSCB 50 is bidirectional, so current may flow from terminal 52 to 54, or from terminal 54 to 52. When turned on, current may flow through switching elements 66 in a forward direction but not a rearward direction. Orientation of multiple separate switching elements 66 can ensure that current flows from terminal 52 to 54 through at least one of the elements 66, and that current flows from terminal 52 to 54 through at least another of the elements 66. Such a device can have the separate elements 66 in an anti-parallel configuration as will be appreciated by those of skill in the art. An example of such a circuit breaker can be found in U.S. patent application Ser. No. 16/707,426 filed on Dec. 9, 2019 which is hereby incorporated herein by reference in its entirety.

The control PCB 60 is provided to monitor current flow between the terminals 52 and 54, as well as to control the solid state devices 66 of the power electronics 58 to regulate and/or interrupt the current flow. Such monitoring and/or control can occur though a communication link/electrical connection 67 which can take any variety of forms, including but not limited to a pin, lead, or other type of conductive device that electrically connects the control PCB 60 to the power electronics 58 and/or other locations of the SSCB 52. Further forms and functions of the electrical connection 67 are described further below and as will also be appreciated by those of skill in the art. The control PCB 60 can be comprised of digital circuitry, analog circuitry, or a hybrid combination of both of these types, which can include any variety of conventional circuit elements, solid state devices, etc. In one form the control PCB 60 includes one or more gate drives to activate the solid state elements 66 of the power electronics 58.

The control PCB 60 includes a printed circuit board (PCB) 68 that can be used to mechanically support and interconnect a variety of circuit elements 70 (only one is shown for simplicity but it will be appreciated that the PCB 68 can include other elements 70). The PCB 68 can take a variety of arrangements including single sided (one copper layer), double sided (two copper layers on both sides of a substrate layer), or multi-layer, to set forth just a few non-limiting examples. The PCB 68 can be made from a variety of materials, typically dielectric in nature, which can include cloth and paper impregnated with a thermoset resin. Common substrate materials include phenolic paper, woven fiberglass, polyimide foils, and polyimide-fluoropolymer composite foils.

In some forms, the printed circuit board 68 is relatively flat having a relatively thin thickness and extending in a planar fashion, but not all printed circuit boards need be arranged in this manner. It will be appreciated that the printed circuit board can have a variety of cross-sectional shapes as viewed in the direction of its thickness, including a square, a rectangular, or another polygonal shape. For example, in the schematic shown in FIG. 1 the shape of the PCB 68 is rectangular having a length along its larger dimension and a width along its shorter dimension. A thickness (not illustrated) will be appreciated to extend into the planar view of FIG. 1). In some forms the printed circuit board can be considered to extend along an elongate axis (e.g. along its length and/or width), where such elongate axes is located within the plane of the planar shaped printed circuit board 68. Although the printed circuit board can extend along each of three separate axes, as shown in the side views of the drawings an elongate axis can be considered the axis of extension that includes a larger dimension than the other axis of extension.

The heat sinks 62 and 64 can be attached within the package 56 by soldering, sintering, glued, or screwed into place, among potential others. Furthermore, the heat sinks 62 and 64 can cover the whole area of the power electronics 58, or only part of it. For example, the heat sinks 62 and/or 64 can extend across an entire distance of one dimension of the power electronics 58 (e.g. its width), but fail to extend across an entire distance of another dimension of the power electronics 58 (e.g. its length).

The heat sinks 62 and 64 can be made of a variety of materials using a variety of different manufacturing processes. For example, the heat sinks 62 and/or 64 can be made of a thermally conductive material such as a metal or polymer. In one form illustrated further below the heat sinks 62 and 64 can include a base from which extends a number of separate heat sink fins 74. The heat sinks 62 and 64 can be made by bonding heat sink fins to a base, the fins can be folded into shape and bonded/brazed/soldered to the base, the fins can be stamped and encapsulated with a die cast base, the heat sink can be forged into shape, fins can be skived onto the base, in the fins can be machined from a stock piece of material to form an integral base and fins, the fins can be CNC machined, the fins can be extruded, etc, etc. When installed the base 72 of the heat sink 64 can extend in parallel with the power electronics package 58 as illustrated in FIG. 1. In one form depicted in FIG. 1 the base 72 extends in parallel with the power electronics package 58, with the base 72 having consistent thickness along the length and/or width of the heat sink, but not all forms of the heat sinks need include a constant thickness base 72. Thus, the base 72 of the heat sink can include an elongate axis of extension as illustrated in FIG. 1 which can be either its length or its width. Although the heat sink 62/64 and/or base 72 can extend along each of three separate axes, as shown in the side views of the drawings an elongate axis can be considered the axis of extension that includes a larger dimension than the other axis of extension.

The fins can take a variety of forms such as pins, foils, and columns. In this regard, the fins 74 can have common cross sectional shapes along their respective lengths, but not all embodiments of the heat sinks need have common shapes in all of their respective fins 74. Two or more different shapes are also contemplated for the fins 74 in any given heat sink.

In some forms the fins 74 can be spaced apart equally along a dimension of the base (e.g. along its length and/or width), but not all forms need include equi-spaced fins. In still other forms, the fins may be equi-spaced in one portion of the heat sink, while an open space is provided for in another portion of the heat sink which is unoccupied by finds. Furthermore, the heat sinks 62 and 64 need not be made from the same materials and/or need not be made using the same manufacturing process. In short, the heat sinks 62 and 64 can be different from one another.

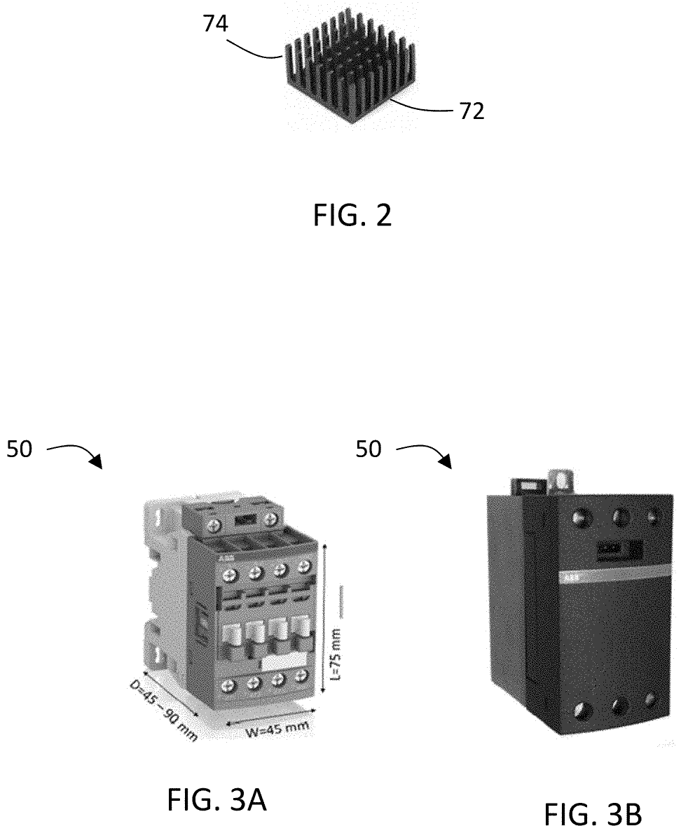

The fins 74 can extend to a vertical height above the base 72 of the heat sink. In some forms, all of the fins 74 can extend to a common height above the base, but in other forms the fins can extend to two or more different heights above the base 72. One nonlimiting embodiment of a heat sink is depicted in FIG. 2 which illustrates several fins 74 extending from a base 72.

In general, the heat sink and electronics package 56 is defined by a package envelope 76 which denotes the volumetric space occupied by the components of the package. The dotted line in FIG. 1 identified by reference numeral 76 is notional only and is used for illustration purposes only in FIG. 1. The dotted line 76 does not reflect the actual volumetric envelope of the package 56 in FIG. 1 as will be appreciated, but nevertheless the concept still applies that an envelope can be identified which encompasses the constituent parts of the package 56. As will be appreciated by the embodiments discussed further below, some forms of the package 56 can be minimized by appropriate relative location and orientation of the constituent components (e.g. power electronics 58 control PCB 60, heat sinks 72 and/or 74) which reduces at least one of a width, height, or depth of the package. In the various forms the control electronics PCB 60 can be mounted in close proximity to one or both of the heat sinks such that a space which is occupied by the heat sink and electronics package 56 is minimized.

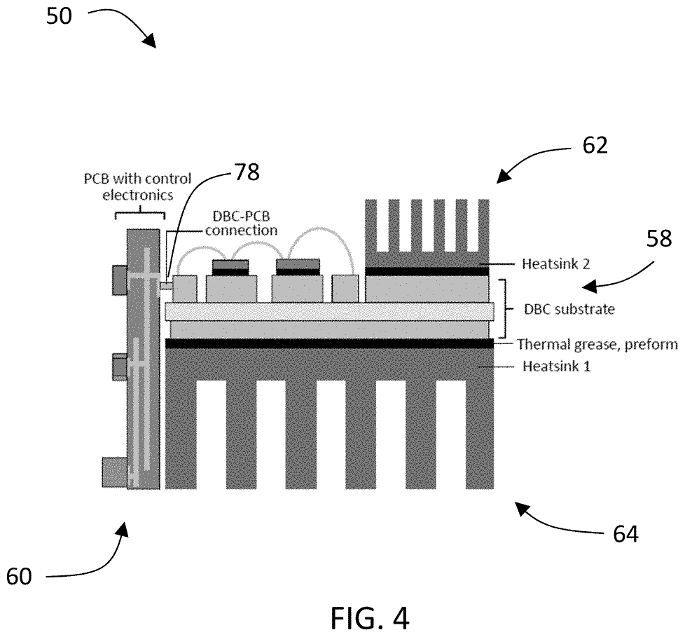

FIGS. 3A and 3B illustrate two different non-limiting embodiments of the SSCB 50 discussed herein. Dimensions are provided for the embodiment illustrated in FIG. 3A, but it will be appreciated that other embodiments may have different dimensions. It will be understood that the embodiments include an outer housing, and wherein the heat sink and electronics package 56 is located at least partially within the outer housing (in some embodiments may be located entirely within the outer housing).

In applications having specific requirements in terms of space and dimensions, the development of a solid state breaker involves a challenge to design a device with miniaturized physical format and able to operate at high currents. The control PCB 60 can be arranged variety of different orientations relative to the power electronics 58, relative to the heat sinks 62 and/or 64, and/or relative to the overall volumetric dimensions of the heat sink and electronics package 56. Dimensions of the heat sink and electronics package 56 are such that the package envelope 76 is minimized to reduce one or more dimensions of the package and/or reduce volumetric requirements needed for incorporation into the electronic switching device 50. The package dimensions can include a height, width, and depth defined by the various portions of the package. For example, the heat sink fans extending from a base of the top heat sink can define one edge, and the heat sink fans extending from a base of the bottom heat sink can define another edge, where the distance between those two edges defines the height of the package. Various attributes of the package can be derived from these constraints. For example, the heat sink and electronics package can be oriented such that the control electronics is positioned to the side of the power electronics.

Turning now to FIG. 4, one embodiment of the SSCB 50 includes the control electronics PCB 60 mounted adjacent to and at an angle relative to the power electronics module 58. As will be appreciated in context of the description above, each of the control electronics 60 and the power electronics 58 include various axes of extension, but it will be understood the some dimensions of the components include longer axes of extension as indicated in the drawings. It is the elongate axes of extension as supported by the drawings that are considered oriented at angles relative to one another. As can be seen, an elongate axis of extension of the control electronics PCB 60 is mounted in a vertical orientation transverse to an elongate axis of extension of the power electronics 58. As used herein, the terms “vertical” and “horizontal” are used for ease of description and are not intended to convey precise limitations in an as-installed configuration of the SSCB 50. In one form the angle can be orthogonal, but other embodiments can include non-right angles.

The control electronics 60 bridges from the heat sink 62 to the heat sink 64 and across the height of the power electronics module 58. The control electronics 60 can extend from the bottom of the fins 74 of the heat sink 64 to the top of the fins 74 of the heat sink 62, but not all embodiments need include such extension. For example, the embodiment illustrated in FIG. 4 shows the control electronics 60 extending from the bottom of the fins 74 of heat sink 64 but failing to reach the top of the fins 74 of the heat sink 62. Other variations in extension of the control electronics 60 are also contemplated.

The power electronics module 58 can take a variety of forms having difference component constructions, including a direct bonded copper substrate, an active metal braze substrate, an embedded substrate, an insulated metals substrate, and a printed circuit board. The embodiment depicted in FIG. 4 illustrates a direct bonded copper (DBC) construction. The power electronics module 58 can have wire or ribbons connecting its various solid state components (illustrated as the arcing filament connecting various portions shown in FIG. 4).

The control PCB 60 can be connected to the power electronics 58 through one or more pins, leads, other similar devices, whether rigid or flexible such as a flexible connector, depicted as reference numeral 78. Reference numeral 78 serves as the communications link 67 described above. FIG. 4 illustrates a DBC-PCB connection.

The embodiment in FIG. 4 also includes thermal grease disposed between the power electronics 58 and each of the heat sinks 62 and 64 to serve as a thermally conductive but electrically insulative material. The thermal grease can be used to bond the heat sinks to the power electronics. The thermal grease is used to eliminate air gaps or spaces from the interface area between the power electronics 58 and either of the sinks 62 and 64. Some forms of the SSCB 50 need not include such a material. For example, in some forms screws can be used to attach the heat sinks to the power electronics.

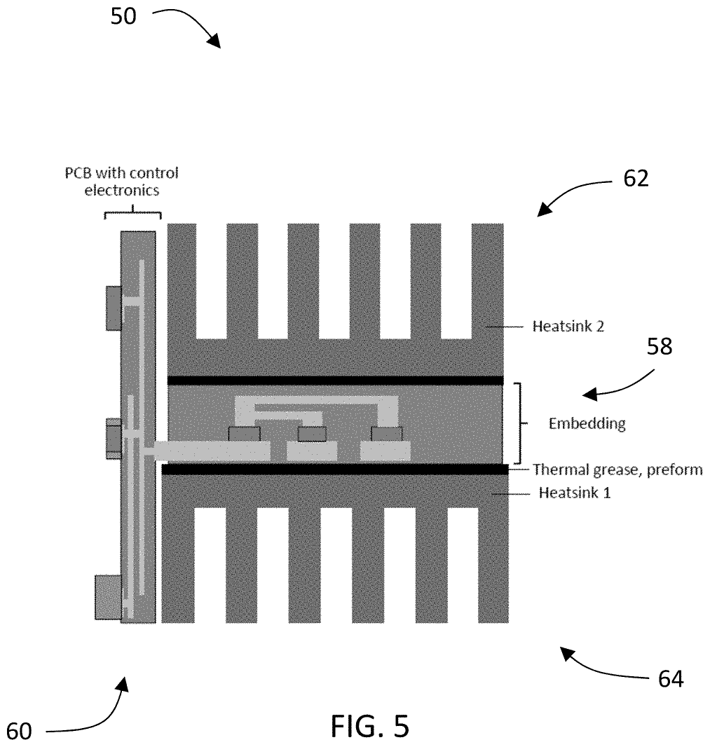

FIG. 5 illustrates another embodiment of the heat sink and electronics control package 56 in which the heat sink 62 extends directly over the top of the power electronics 58. The control electronics 60 is positioned laterally to the heat sinks 62 and 64 and extends nearly to the top and bottom of the respective heat sinks. As in FIG. 4, FIG. 5 can include thermal grease between the heat sinks and power electronics 58. The control electronics 60 is connected to the lateral side of the power electronics 58 and toward the side closest to the heat sink 64, but other locations of the connection are also contemplated.

One manner of constructing the package 56 of any of the embodiments disclosed herein includes attaching one or more heat sinks to the power electronics 58, locating the control electronics 60 to the side of the power electronics and orienting the control electronics 60 in a vertical orientation (or other suitable angle), and connecting the control PCB 60 to the power electronics 58.

One aspect of the present application includes an apparatus comprising a solid state switching device having an outer housing as well as a first electrical power terminal and a second electrical power terminal, the solid state switching device includes: a power electronics module disposed within the housing and having at least one solid-state component useful to regulate flow of current between the first electrical power terminal and second electrical power terminal; a first heat sink positioned on a first side of the power electronics module and a second heat sink positioned on a second side of the power electronics, the first side of the power electronics opposite the second side of the power electronics, each of the first heat sink and second heat sink in thermal contact with the power electronics module; and a control electronics printed circuit board disposed in the housing and positioned on a lateral side of the power electronics module, the lateral side extending between the first side and the second side of the power electronics, the control electronics coupled to the power electronics through an electrical connection.

A feature of the present application includes wherein the control electronics printed circuit board extends past the first side to be adjacent to the first heat sink and also extends past the second side to be adjacent to the second heat sink.

Another feature of the present application includes wherein the power electronics includes a printed circuit board, and wherein the control electronics printed circuit board is electrically connected to the printed circuit board of the power electronics.

Yet another feature of the present application includes wherein the power electronics includes a direct bonded copper substrate (DBC), and wherein the DBC is connected to the control electronics printed circuit board through a DBC-to-printed circuit board connection.

Still another feature of the present application includes wherein the first heat sink extends over only part of the power electronics along the first side, and wherein the second heat sink extends over the second side of the power electronics.

Yet still another feature of the present application includes wherein the control electronics printed circuit board includes an elongate axis of extension, and wherein the elongate axis of extension of the control electronics printed circuit board is mounted at a non-right angle relative to the elongate axis of extension of the power electronics.

Still yet another feature of the present application includes wherein the control electronics printed circuit board is connected to the power electronics through a flexible connector.

A further feature of the present application includes wherein the at least one solid state component of the power electronics module is one of a FET, thyristor, IGBT, and an IGCT.

Another aspect of the present application includes an apparatus comprising: a solid state circuit breaker structured to monitor current flow in a circuit connection between a first power terminal and a second power terminal, the solid state circuit breaker including a heat sink and electronics package disposed within a housing of the solid state circuit breaker, the heat sink and electronics package including: a power electronics module including at least one switchable solid-state component, a first heat sink positioned on a first side of and in thermal communication with the power electronics module, a second heat sink positioned on a second side of and in thermal communication with the power electronics module, and a control electronics printed circuit board (PCB) located on a lateral side of the power electronics module between the first and second side and extending from the first heat sink, past the control electronics PCB, to the second heat sink, wherein the control electronics PCB is structured to monitor current flow between the first power terminal and the second power terminal and change an operating state of at least one solid state device of the power electronics based upon the monitored current flow.

A feature of the present application includes wherein the power electronics includes at least one of direct bonded copper substrate, an active metal braze substrate, an embedded substrate, an insulated metals substrate, and a printed circuit board.

Another feature of the present application includes wherein a substrate of the power electronics is ceramic.

Yet another feature of the present application includes wherein the power electronics is connected to the control electronics printed circuit board through one of a pin, lead, and a flexible connection.

Still another feature of the present application includes wherein the control electronics PCB includes a gate driver, the gate driver structured to command the at least one solid state component of the power electronics module.

Still yet another feature of the present application includes wherein the first heat sink extends only over part of the power electronics module.

Yet still another feature of the present application includes wherein the first heat sink includes a plurality of first heat sinks all located on the first side of the power electronics.

A further feature of the present application includes wherein the at least one solid state component of the power electronics module is one of a FET, thyristor, JFET, IGBT, and an IGCT.

A yet further feature of the present application includes wherein the control electronics PCB includes an elongate axis of extension, the power electronics includes an elongate axis of extension, and wherein the elongate axis of extension of the control electronics printed circuit board is mounted at an angle relative to the elongate axis of extension of the power electronics.

Yet another aspect of the present application includes a method comprising: affixing a first heat sink to a first side of a power electronics module in an electronic switching device; coupling a second heat sink to a second side of the electronic switching device, the second side opposite the first side; locating an electronic control printed circuit board (PCB) adjacent to the power electronics module such that an axis of extension of the electronic control PCB extends at an angle relative to the power electronics module; and connecting an electronic control PCB to the power electronics module.

A feature of the present application includes wherein the locating includes orienting an elongate axis of extension of the electronic control PCB at a right angle to an elongate axis of extension of the power electronics module.

Another feature of the present application further includes connecting the control electronics PCB to the power electronics module using a flexible connector.

While the invention has been illustrated and described in detail in the drawings and foregoing description, the same is to be considered as illustrative and not restrictive in character, it being understood that only the preferred embodiments have been shown and described and that all changes and modifications that come within the spirit of the inventions are desired to be protected. It should be understood that while the use of words such as preferable, preferably, preferred or more preferred utilized in the description above indicate that the feature so described may be more desirable, it nonetheless may not be necessary and embodiments lacking the same may be contemplated as within the scope of the invention, the scope being defined by the claims that follow. In reading the claims, it is intended that when words such as “a,” “an,” “at least one,” or “at least one portion” are used there is no intention to limit the claim to only one item unless specifically stated to the contrary in the claim. When the language “at least a portion” and/or “a portion” is used the item can include a portion and/or the entire item unless specifically stated to the contrary. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings. Also unless specified or limited otherwise, terms such as “lateral,” “top,” “bottom,” are used for ease of describing relative orientations/locations with respect to the drawings, and are not meant to imply an absolute orientation/location in an as-installed configuration.

What is claimed is:

1. An apparatus comprising:
a solid state switching device having an outer housing as well as a first electrical power terminal and a second electrical power terminal, the solid state switching device includes:
a power electronics module disposed within the housing and having at least one solid-state component useful to regulate flow of current between the first electrical power terminal and second electrical power terminal;
a first heat sink positioned on a first side of the power electronics module and a second heat sink positioned on a second side of the power electronics, the first side of the power electronics opposite the second side of the power electronics, each of the first heat sink and second heat sink in thermal contact with the power electronics module; and
a control electronics printed circuit board positioned on a lateral side of the power electronics module, the lateral side extending between the first side and the second side of the power electronics, the control electronics coupled to the power electronics through an electrical connection.

2. The apparatus of claim 1, wherein the control electronics printed circuit board extends past the first side to be adjacent to the first heat sink and also extends past the second side to be adjacent to the second heat sink.

3. The apparatus of claim 2, wherein the power electronics includes a printed circuit board, and wherein the control electronics printed circuit board is electrically connected to the printed circuit board of the power electronics.

4. The apparatus of claim 2, wherein the power electronics includes a direct bonded copper substrate (DBC), and wherein the DBC is connected to the control electronics printed circuit board through a DBC-to-printed circuit board connection.

5. The apparatus of claim 2, wherein the first heat sink extends over only part of the power electronics along the first side, and wherein the second heat sink extends over the second side of the power electronics.

6. The apparatus of claim 1, wherein the control electronics printed circuit board includes an elongate axis of extension, and wherein the elongate axis of extension of the control electronics printed circuit board is mounted at a non-right angle relative to the elongate axis of extension of the power electronics.

7. The apparatus of claim 1, wherein the control electronics printed circuit board is connected to the power electronics through a flexible connector.

8. The apparatus of claim 1, wherein the at least one solid state component of the power electronics module is one of a FET, thyristor, IGBT, and an IGCT.

9. An apparatus comprising:
a solid state circuit breaker structured to monitor current flow in a circuit connection between a first power terminal and a second power terminal, the solid state circuit breaker including a heat sink and electronics package disposed within a housing of the solid state circuit breaker, the heat sink and electronics package including: a power electronics module including at least one switchable solid-state component, a first heat sink positioned on a first side of and in thermal communication with the power electronics module, a second heat sink positioned on a second side of and in thermal communication with the power electronics module, and a control electronics printed circuit board (PCB) located on a lateral side of the power electronics module between the first and second side and extending from the first heat sink, past the control electronics PCB, to the second heat sink, wherein the control electronics PCB is structured to monitor current flow between the first power terminal and the second power terminal and change an operating state of at least one solid state device of the power electronics based upon the monitored current flow.

10. The apparatus of claim 9, wherein the power electronics includes at least one of direct bonded copper substrate, an active metal braze substrate, an embedded substrate, an insulated metals substrate, and a printed circuit board.

11. The apparatus of claim 10, wherein a substrate of the power electronics is ceramic.

12. The apparatus of claim 10, wherein the power electronics is connected to the control electronics printed circuit board through one of a pin, lead, and a flexible connection.

13. The apparatus of claim 9, wherein the control electronics PCB includes a gate driver, the gate driver structured to command the at least one solid state component of the power electronics module.

14. The apparatus of claim 9, wherein the first heat sink extends only over part of the power electronics module.

15. The apparatus of claim 9, wherein the first heat sink includes a plurality of first heat sinks all located on the first side of the power electronics.

16. The apparatus of claim 9, wherein the at least one solid state component of the power electronics module is one of a FET, thyristor, JFET, IGBT, and an IGCT.

17. The apparatus of claim 9, wherein the control electronics PCB includes an elongate axis of extension, the power electronics includes an elongate axis of extension, and wherein the elongate axis of extension of the control electronics printed circuit board is mounted at an angle relative to the elongate axis of extension of the power electronics.

18. A method comprising:
affixing a first heat sink to a first side of a power electronics module in an electronic switching device;
coupling a second heat sink to a second side of the electronic switching device, the second side opposite the first side;
locating an electronic control printed circuit board (PCB) adjacent to the power electronics module such that an axis of extension of the electronic control PCB extends at an angle relative to the power electronics module; and
connecting an electronic control PCB to the power electronics module.

19. The method of claim 18, wherein the locating includes orienting an elongate axis of extension of the electronic control PCB at a right angle to an elongate axis of extension of the power electronics module.

20. The method of claim 18, which further includes connecting the control electronics PCB to the power electronics module using a flexible connector.
